(19) United States
(12) Patent Application Publication
(10) Pub. No.: US 2024/0414982 A1
(43) Pub. Date: Dec. 12, 2024

(54) DISPLAY DEVICE AND METHOD FOR MANUFACTURING SAME

(71) Applicant: Samsung Display Co., LTD., Yongin-si (KR)

(72) Inventors: HYUNSEUNG SEO, Yongin-si (KR); YONGKYU KANG, Yongin-si (KR); JIHYUN KO, Yongin-si (KR); Jinsu NAM, Yongin-si (KR); Junho LEE, Yongin-si (KR)

(21) Appl. No.: 18/617,991

(22) Filed: Mar. 27, 2024

(30) Foreign Application Priority Data
Jun. 9, 2023 (KR) 10-2023-0073979

(51) Int. Cl. H10K 59/80; H01L 33/56; H10K 71/50; H10K 102/00

(52) U.S. Cl. CPC H10K 59/873; H01L 33/56; H10K 71/50; H01L 2933/005; H10K 2102/311

(57) ABSTRACT

A display device includes a display panel and a cover window disposed on the display panel. The display panel includes a deformation part, which is curvedly deformable, and a non-deformation part adjacent to the deformation part. The cover window includes a first cover part overlapping the non-deformation part and including crystallized glass, and a second cover part overlapping the deformation part and not including the crystallized glass.

This application claims priority to Korean Patent Application No. 10-2023-0073979, filed on Jun. 9, 2023, and all the benefits accruing therefrom under 35 U.S.C. § 119, the content of which in its entirety is herein incorporated by reference.

### BACKGROUND

### 1. Field

The disclosure herein relates to a display device including a cover window, and a manufacturing method for the same.

### 2. Description of the Related Art

A display device displays various images on a display screen to provide information to a user. In general, the display device displays information in an allocated screen. Recently, flexible display devices including flexible display panels capable of sliding or folding are being developed. The flexible display device, unlike a rigid display device, may be foldable, rollable, or bendable. The flexible display device, the shape of which is variously deformable, may be portable regardless of the size of the existing screen, thereby improving the user's convenience.

### SUMMARY

For a flexible display device, the shape of which is deformable, it is desired to maintain the reliability and stability of members constituting the display device as the shape is deformed.

The disclosure provides a display device including a cover window in which the thickness difference is reduced and the impact resistance is improved, and a manufacturing method for the display device.

An embodiment of the invention provides a display device including a display panel including a deformation part, which is curvedly deformable, and a non-deformation part adjacent to the deformation part, and a cover window disposed on the display panel, where the cover window includes a first cover part overlapping the non-deformation part and including crystallized glass, and a second cover part overlapping the deformation part and not including the crystallized glass.

In an embodiment, the crystallized glass may include a crystal having a diameter in a range of about 10 nanometers (nm) to about 100 nm.

In an embodiment, the second cover part may include amorphous glass.

In an embodiment, the cover window may further include a coating layer overlapping the second cover part.

In an embodiment, the coating layer may not overlap the first cover part.

In an embodiment, a refractive index of the coating layer may be substantially the same as a refractive index of the second cover part.

In an embodiment, the coating layer may include an optically transparent polymer resin.

In an embodiment, a first thickness of the first cover part may be greater than a second thickness of the second cover part.

In an embodiment, a thickness of the second cover part may be in a range of about 10 micrometers (μm) to about 100 μm.

In an embodiment, the cover window may further include a third cover part disposed between the first cover part and the second cover part and including a slope.

In an embodiment, the third cover part may not include the crystallized glass, and include amorphous glass.

In an embodiment of the invention, a manufacturing method for a display device includes preparing a display panel which includes a deformation part, which is curvedly deformable, and a non-deformation part adjacent to the deformation part, and forming a cover window which includes a first cover part overlapping the non-deformation part and including crystallized glass, and a second cover part overlapping the deformation part and not including the crystallized glass, and the forming the cover window includes preparing a preliminary cover window which includes a preliminary first cover part and a preliminary second cover part adjacent to the preliminary first cover part, etching the preliminary second cover part to form the second cover part, and radiating laser to the preliminary first cover part to form the first cover part before or after the forming the second cover part.

In an embodiment, the preliminary first cover part may include amorphous glass, and the forming the first cover part may include radiating the laser to the amorphous glass to form the crystallized glass.

In an embodiment, the laser may not be radiated to the preliminary second cover part.

In an embodiment, a thickness of the preliminary second cover part may be reduced by the etching.

In an embodiment, etching the preliminary second cover part may include providing an etching solution the preliminary second cover part.

In an embodiment, the cover window may further include a third cover part disposed between the first cover part and the second cover part and including a slope, and the third cover part may be formed in a same process as the etching the preliminary second cover part.

In an embodiment, the forming the cover window may further include, after the forming the first cover part and the forming the second cover part, immersing the first cover part and the second cover part in molten salt.

In an embodiment, the forming the cover window may further include, after the forming the first cover part and the forming the second cover part, forming a coating layer on one surface of the second cover part by providing an optically transparent polymer resin thereon.

In an embodiment, the forming the cover window may further include, after the forming the first cover part and the forming the second cover part, forming a print layer on one surface of the first cover part and one surface of the second cover part, and forming an anti-fingerprint layer on another surface of the first cover part and another surface of the second cover part.

### BRIEF DESCRIPTION OF THE DRAWINGS

The above and other features of the invention will become more apparent by describing in further detail embodiments thereof with reference to the accompanying drawings, in which:

FIG. 1A is a perspective view of a display device according to an embodiment;

FIG. 1B is a perspective view of a display device according to an embodiment;

FIG. 2A is a perspective view of a display device according to an embodiment;

FIG. 2B is a perspective view of a display device according to an embodiment;

FIG. 3A is a perspective view of a display device according to an embodiment;

FIG. 3B is a perspective view of a display device according to an embodiment;

FIG. 3C is a perspective view of a display device according to an embodiment;

FIG. 4 is an exploded perspective view of a display device according to an embodiment;

FIG. 5 is a perspective view illustrating a portion of a display device according to an embodiment;

FIG. 6 is a perspective view illustrating a portion of a display device according to an embodiment;

FIG. 7 is a cross-sectional view illustrating a portion taken along line I-I′ of FIG. 5;

FIG. 8 is a cross-sectional view illustrating a portion of a display device according to an embodiment;

FIG. 9A is a cross-sectional view illustrating a portion of a display device according to an embodiment;

FIG. 9B is a cross-sectional view illustrating a portion of a display device according to an embodiment;

FIG. 9C is a cross-sectional view illustrating a portion of a display device according to an embodiment;

FIG. 10 is a graph showing ball drop test results for Comparative Example and Example;

FIG. 11 is a graph showing the transmittance according to a wavelength in Example;

FIG. 12A is a flowchart illustrating a manufacturing method for a display device according to an embodiment;

FIG. 12B is a flowchart illustrating a manufacturing method for a display device according to an embodiment;

FIG. 13 is a diagram schematically illustrating a manufacturing operation of a display device according to an embodiment;

FIG. 14 is a diagram schematically illustrating a manufacturing operation of a display device according to an embodiment;

FIG. 15 is a diagram schematically illustrating a manufacturing operation of a display device according to an embodiment;

FIG. 16 is a diagram schematically illustrating a manufacturing operation of a display device according to an embodiment;

FIG. 17 is a diagram schematically illustrating a manufacturing operation of a display device according to an embodiment; and

FIG. 18 is a diagram schematically illustrating a manufacturing operation of a display device according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the invention. Similarly, a second element, component, region, layer or section may be termed a first element, component, region, layer or section.

Also, terms of “below”, “on lower side”, “above”, “on upper side”, or the like may be used to describe the relationships of the elements illustrated in the drawings. These terms have relative concepts and are described on the basis of the directions indicated in the drawings.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described with reference to the accompanying drawings.

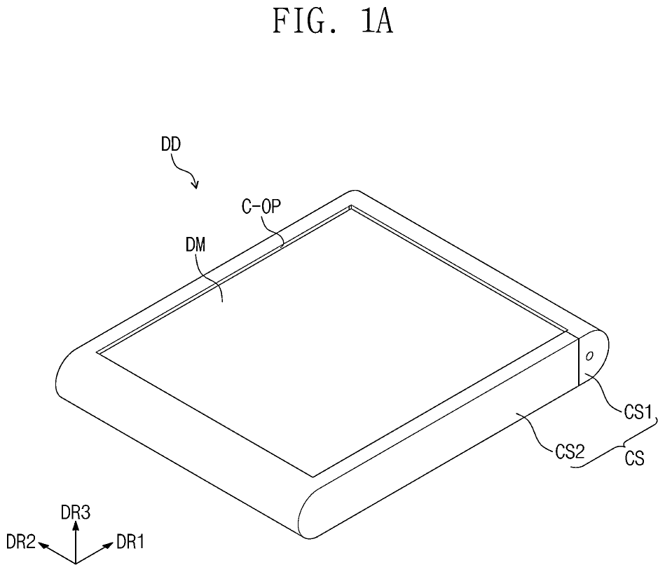

FIG. 1A is a perspective view of a display device according to an embodiment. FIG. 1B is a perspective view illustrating a sliding process of the display device illustrated in FIG. 1A. FIG. 1A illustrates a display device DD which operates in a first mode, and FIG. 1B illustrates the display device DD which operates in a second mode.

The display device DD according to an embodiment may be activated in response to electrical signals. The display device DD may be a flexible device. For example, the display device DD may be a television, a billboard, a monitor, a portable electronic device, a tablet computer, a car navigation system, a game console, a personal computer, a laptop computer, or a wearable device, but an embodiment of the invention is not limited thereto. FIG. 1A illustrates an embodiment where the display device DD is a portable electronic device capable of a sliding operation.

Referring to FIGS. 1A and 1B, an embodiment of the display device DD may include a display module DM, and a case CS in which the display module DM is accommodated. At least a portion of the display module DM may be exposed to the outside through a display opening C-OP defined in an upper part of the case CS.

The case CS may include a first case CS1 and a second case CS2. The first case CS1 and the second case CS2 may be coupled to each other to accommodate the display module DM. The first case CS1 may be coupled to the second case CS2 to be movable in a direction parallel to a first directional axis DR1. The first case CS1, which is coupled to the second case CS2, may be movable to be closer to, or to be away from the second case CS2.

A display surface of the display module DM, exposed by the display opening C-OP, may be parallel to a plane defined by the first directional axis DR1 and a second directional axis DR2 crossing the first directional axis DR1. The display module DM may display an image or video on the display surface, parallel to the plane defined by the first directional axis DR1 and the second directional axis DR2, toward a direction parallel to a third directional axis DR3.

In this specification, the first directional axis DR1 and the second directional axis DR2 may cross at right angles, and the third directional axis DR3 may be the normal direction of the plane defined by the first directional axis DR1 and the second directional axis DR2. The thickness direction of the display device DD may be a direction parallel to the third directional axis DR3. An upper surface (or upper side, upper part) and a lower surface (or lower side, lower part) may be defined on the basis of the third directional axis DR3. The upper surface (or upper side, upper part) of a component refers to a surface (or direction) adjacent to the display surface, and the lower surface (or lower side, lower part) of the component refers to a surface (or direction) spaced apart from the display surface. A cross-section refers to a surface parallel to the thickness direction DR3, and a plane refers to a plane perpendicular to the thickness direction DR3. The plane refers to a plane defined by the first directional axis DR1 and the second directional axis DR2.

Directions indicated by the first to third directional axes DR1, DR2, and DR3, described in this specification, may be relative concepts, and may thus be changed to other directions. In addition, the directions indicated by the first to third directional axes DR1, DR2, and DR3 may be described as first to third directions, and may be denoted as the same reference numerals or symbols.

Referring to FIGS. 1A and 1B, the area of the display surface of the display module DM, exposed through the display opening C-OP of the case CS, may be controlled based on movement of the first case CS1. As the first case CS1 moves, the opening area of the display opening C-OP may increase in the first direction DR1.

The display module DM may be a flexible display module, and may be supported by a supporting layer disposed under the display module DM. When the first case CS1 moves in the first direction DR1, the supporting layer connected to the first case CS1 may also move in the first direction DR1. Accordingly, the display module DM disposed on the supporting layer may also move in the first direction DR1 along the movement of the first case CS1. As the end of the display module DM moves in the first direction DR1 with the first case CS1, one portion of the display module DM, which has been accommodated in the second case CS2 in the first mode, may be exposed to the outside, and the display surface of the display module DM, exposed through the display opening C-OP, may be extended.

FIG. 1A illustrates the display device DD in the first mode, among operational statuses of the display device DD, where the first case CS1 is disposed most adjacent to the second case CS2 along the first direction DR1. In the first mode, one portion extending from one region of the display module DM that is exposed through the display opening C-OP may be folded with a predetermined curvature to be accommodated in the second case CS2. The first mode, where the display surface of the display module DM is set to a default size, may be defined as a default mode.

FIG. 1B illustrates the display device DD in the second mode, among operational statuses of the display device DD, where the first case CS1 is disposed farthest apart from the second case CS2 along the first direction DR1. In the display device DD in the second mode, compared to the first mode, the area of the display surface of the display module DM, exposed through the display opening C-OP, may be increased. That is, the second mode may be defined as an extended mode where the display surface is extended more than in the default mode.

The first mode and the second mode of the display device DD may be determined based on the sliding operations of the case CS and the display module DM. As a user moves the display device DD from the first mode to the second mode, the display surface of the display device DD may extend, and the user may view an image or video through the extended display surface. In addition, as the user moves the display device DD from the second mode to the first mode, the display surface of the display device DD may shrink, and the user may view the video through the shrunk display surface. That is, as the user selects either of the first mode or the second mode to operate the display device DD, the area of the display surface of the display device DD exposed from the case CS may be variously controlled.

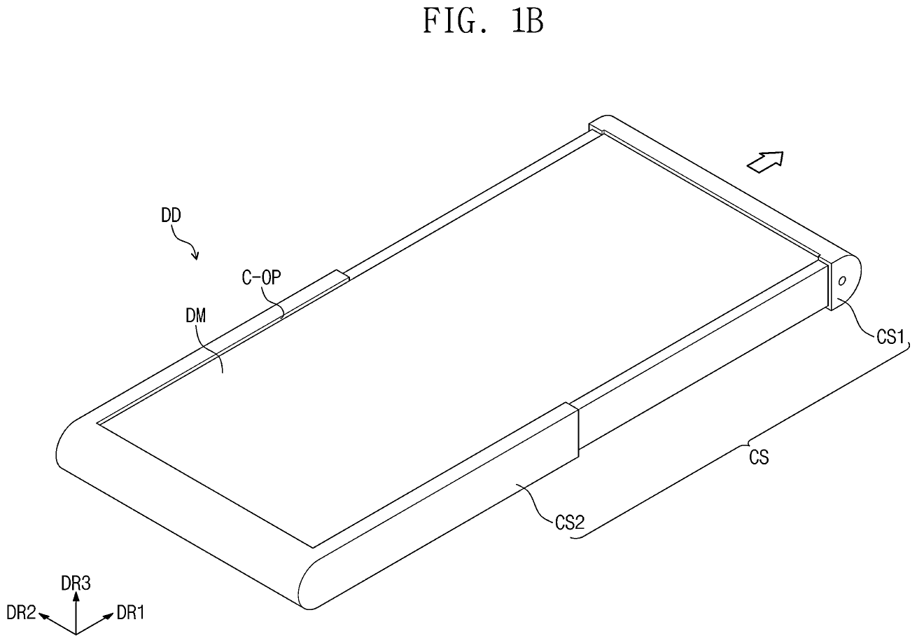

FIG. 2A is a perspective view of a display device according to another embodiment of the invention. FIG. 2B is a perspective view illustrating a sliding process of the display device illustrated in FIG. 2A. FIG. 2A illustrates a display device DD-a which operates in a first mode, and FIG. 2B illustrates the display device DD-a which operates in a second mode.

Referring to FIGS. 2A and 2B, an embodiment of the display device DD-a may include a display module DM-a and a case CS-a. The case CS-a may include first to third cases CS1, CS2, and CS3. The display device DD-a illustrated in FIGS. 2A and 2B is substantially the same as the display device DD illustrated in FIGS. 1A and 1B except that the display device DD-a further includes a third case CS3.

The first to third cases CS1, CS2, and CS3 may be coupled to each other to accommodate the display module DM-a. The first case CS1 may be coupled to the second case CS2 to be movable in a direction parallel to a first directional axis DR1. The first case CS1, which is coupled to the second case CS2, may be movable to be closer to, or to be away from the second case CS2. The first case CS1 and the third case CS3 may be spaced apart from each other with the second case CS2 therebetween. The first case CS1 and the third case CS3 may be movable in directions away from each other or opposite directions, respectively. The third case CS3 may be coupled to the second case CS2 to be movable in a direction parallel to a fourth directional axis DR4. The third case CS3, which is coupled to the second case CS2, may be movable to be closer to, or to be away from the second case CS2.

In this specification, the fourth directional axis DR4 may be a direction opposed to the first directional axis DR1. A direction indicated by the fourth directional axis DR4, described in this specification, may be a relative concept, and may thus be changed to another direction. In addition, the direction indicated by the fourth directional axis DR4 may be described as a fourth direction, and may be denoted by the same reference numeral or symbol.

Referring to FIGS. 2A and 2B, the area of the display surface of the display module DM-a exposed through the display opening C-OP of the case CS-a may be controlled based on movement of the first and third cases CS1 and CS3. As the first case CS1 moves, the opening area of the display opening C-OP may be increased in the first direction DR1. As the third case CS3 moves, the opening area of the display opening C-OP may be increased in the fourth direction DR4.

In an embodiment, as shown in FIGS. 2A and 2B, one portion of the display module DM-a may be accommodated in the first case CS1 in the first mode. As the one portion of the display module DM-a moves with the first case CS1 in the first direction DR1, the one portion of the display module DM-a which has been accommodated in the first case CS1 in the first mode may be exposed to the outside, and the display surface of the display module DM-a exposed through the display opening C-OP may be extended.

In such an embodiment, as shown in FIGS. 2A and 2B, another portion of the display module DM-a may be accommodated in the third case CS3 in the first mode. When the third case CS3 moves in the fourth direction DR4, a supporting layer connected to the third case CS3 may also move in the fourth direction DR4. Accordingly, the display module DM-a disposed on the supporting layer may also move in the fourth direction DR4 along the movement of the third case CS3. As the another portion of the display module DM-a moves with the third case CS3 in the fourth direction DR4, the another portion of the display module DM-a which has been accommodated in the third case CS3 in the first mode may be exposed to the outside, and the display surface of the display module DM-a exposed through the display opening C-OP may be extended.

FIG. 2A illustrates the display device DD-a in the first mode, among operational statuses of the display device DD-a, where the first and third cases CS1 and CS3 are disposed most adjacent to the second case CS2 along the first and fourth directions DR1 and DR4, respectively. In the first mode, one portion extending from one region of the display module DM-a exposed through the display opening C-OP may be folded with a predetermined curvature to be accommodated in each of the first and third cases CS1 and CS3. The first mode, where the display surface of the display module DM-a is set to a default size, may be defined as a default mode.

FIG. 2B illustrates the display device DD-a in a second mode, among the operational statuses of the display device DD-a, where the first case CS1 is disposed farthest apart from the second case CS2 along the first direction DR1, and the third case CS3 is disposed farthest apart from the second case CS2 along the fourth direction DR4. In the display device DD-a in the second mode, compared to the first mode, the area of the display surface of the display module DM-a, exposed through the display opening C-OP, may be increased. That is, the second mode, where the display surface is more extended than in the default mode, may be defined as an extended mode.

As a user moves the display device DD-a from the first mode to the second mode, the display surface of the display device DD-a may extend, and the user may view a video through the extended display surface. In addition, the user may move the display device DD-a from the second mode to the first mode, the display surface of the display device DD-a may shrink, and the user may view the video through the shrunk display surface. That is, as the user selects either of the first mode or the second mode to operate the display device DD-a, the area of the display surface of the display device DD-a, exposed from the case CS-a, may be variously controlled.

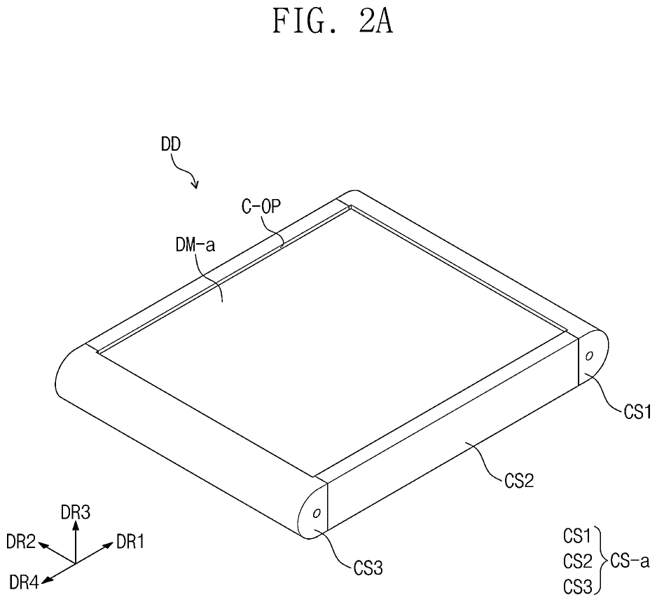

FIG. 3A is a perspective view of a display device according to another embodiment of the invention. FIG. 3B is a perspective view illustrating the display device illustrated in FIG. 3A in an inner-folding process. FIG. 3C is a perspective view illustrating the display device illustrated in FIG. 3A in an outer-folding process. FIGS. 3A to 3C illustrate an embodiment where a display device DD-b is a portable electronic device capable of a folding operation.

Referring to FIG. 3A, an embodiment of the display device DD-b may display a video (or image) IM-b through a display surface DS-b. The display surface DS-b may include an active region F-AA and a peripheral region F-NAA. The active region F-AA may be activated in response to electrical signals. The display device DD-b may display the video IM-b through the active region F-AA. In addition, in the active region F-AA, various types of external inputs may be detected. The peripheral region F-NAA may be adjacent to the active region F-AA. The peripheral region F-NAA may surround the active region F-AA. Accordingly, the shape of the active region F-AA may be substantially defined by the peripheral region F-NAA. However, this is an example, and the peripheral region F-NAA may be disposed adjacent only to one side of the active region F-AA, or may also be omitted. The display surface DS-b may include a flat surface defined by a first directional axis DR1 and a second directional axis DR2.

A rear surface ES of the display device DD-b may be a surface facing the display surface DS-b. For example, the rear surface ES may be an outer surface of the display device DD-b, and may thus not display the video or image. Alternatively, the rear surface ES may also function as a second display surface on which the video or image is displayed.

The display device DD-b may include a folding region FA1 and non-folding regions NFA1 and NFA2. The display device DD-b may include a plurality of non-folding regions NFA1 and NFA2. The display device DD-b may include a first non-folding region NFA1 and a second non-folding region NFA2 with the folding region FA1 therebetween.

FIGS. 3A to 3C illustrate an embodiment where the display device DD-b includes a single folding region FA1, but this is an example, and the display device DD-b may have a plurality of folding regions defined therein. In addition, the display device DD-b may be folded or foldable about a plurality of folding axes such that portions of the display surface DS-b face each other, and the number of the folding axes and the number of non-folding regions accordingly are not limited to any one embodiment of the invention.

Referring to FIGS. 3B and 3C, an embodiment of the display device DD-b may be folded about a first folding axis FX1. The first folding axis FX1 illustrated in FIGS. 3B and 3C may be an imaginary axis extending in the first direction DR1, and the first folding axis FX1 may be parallel to a long-side direction of the display device DD-b. However, this is an example, and the extending direction of the first folding axis FX1 is not limited to the first direction DR1.

The first folding axis FX1 may extend along the first directional axis DR1 on the display surface DS-b, or extend along the first directional axis DR1 under the rear surface ES. Referring to FIG. 3B, an embodiment of the display device DD-b may be inner-folded such that the first non-folding region NFA1 and the second non-folding region NFA2 face each other and the display surface DS-b is not exposed to the outside. Referring to FIG. 3C, the display device DD-b may be folded about the first folding axis FX1, and deformed to an outer-folded status in which one region of the rear surface ES overlapping the first non-folding region NFA1 and the other region overlapping the second non-folding region NFA2 face each other.

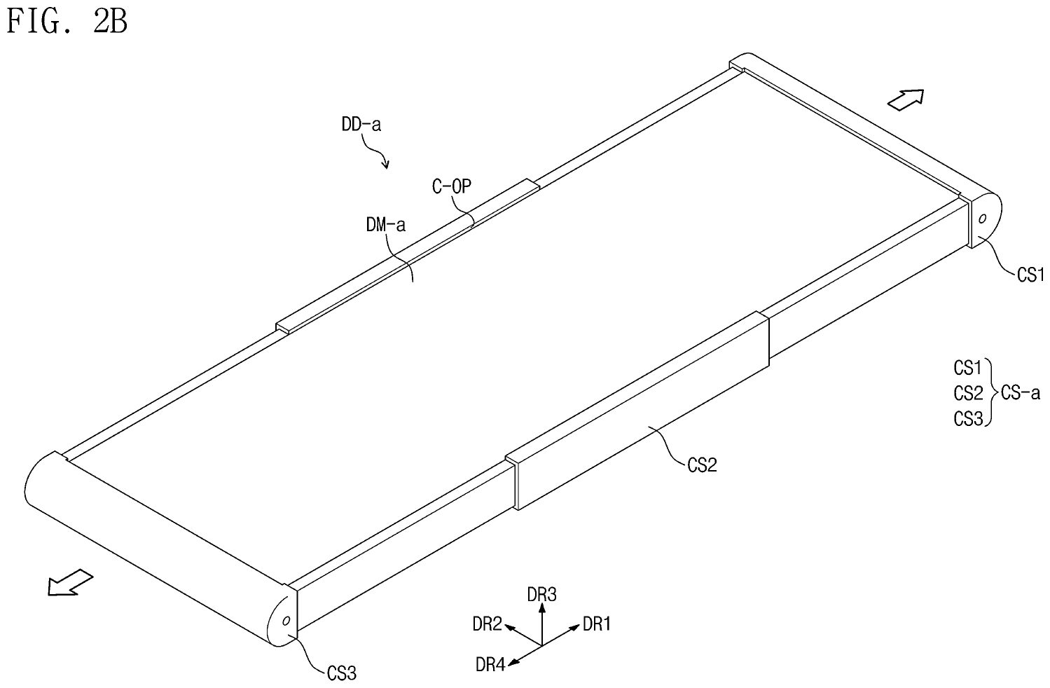

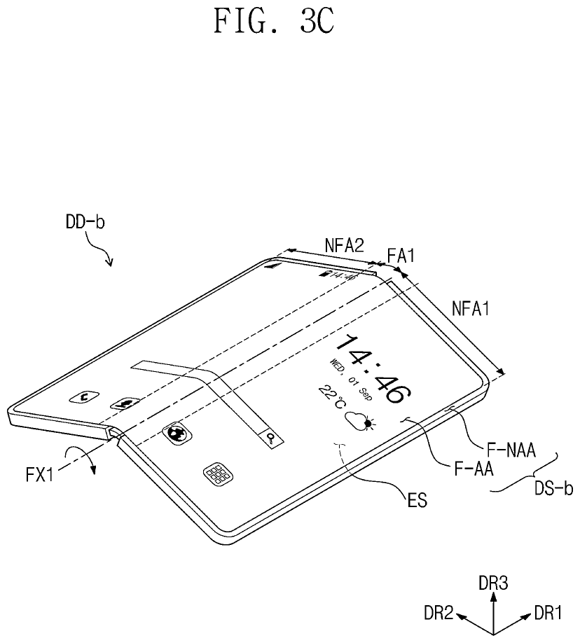

FIG. 4 is an exploded perspective view of the display device DD-b illustrated in FIG. 3A. Referring to FIG. 4, an embodiment of the display device DD-b may include a display module DM-b. The display module DM-b may include a display panel DP and a cover window WP. In addition, the display device DD-b may further include a supporting member SM disposed under the display module DM-b, and a housing HAU that accommodates the display module DM-b and the supporting member SM. Although not illustrated in FIG. 4, an input-sensing layer ISL (see FIG. 7) and an optical layer RPL (see FIG. 7) may be disposed between the display panel DP and the cover window WP. The optical layer RPL (see FIG. 7) may be disposed on the input-sensing layer ISL (see FIG. 7).

The housing HAU may include a material having relatively high rigidity. For example, the housing HAU may include a plurality of frames and/or plates, each including or composed of glass, plastic, or metal. The housing HAU may provide a predetermined accommodating space. The display module DM-b may be accommodated in the accommodating space, and protected from external impact.

The supporting member SM may include a metal material or polymer material. For example, the supporting member SM may include or be formed by including stainless steel, aluminum, or an alloy thereof. Alternatively, the supporting member SM may include or be formed of carbon fiber reinforced plastic (CFRP), etc. However, an embodiment of the invention is not limited thereto, and the supporting member SM may include a non-metal material, plastic, glass fiber reinforced plastic, or glass.

Although not illustrated in the drawing, the display device DD-b may further include a cushion layer, a shielding layer, etc. disposed under the supporting member SM. The cushion layer may include elastomer, etc. such as sponge, foam, or a urethane resin. The shielding layer may be an electromagnetic shielding layer or a heat dissipation layer.

The display panel DP may be an emission-type display panel. For example, the display panel DP may be an organic light-emitting display panel, an inorganic light-emitting display panel, a micro-light emitting diode (LED) display panel, or a nano-LED display panel. The display panel DP may include a display region DA and a non-display region NDA. The non-display region NDA may be adjacent to the display region DA and may surround at least a portion of the display region DA. The display region DA may display the video IM-b (see FIG. 3A), and the non-display region NDA may not display the video IM-b (see FIG. 3A). Although not illustrated in the drawing, a drive circuit, etc. may be disposed on one side of the non-display region NDA.

The display panel DP may be a flexible display panel. The display panel DP may include a deformation part TF-F, a first non-deformation part NTF1-F, and a second non-deformation part NTF2-F. The first non-deformation part NTF1-F and the second non-deformation part NTF2-F may be spaced apart from each other with the deformation part TF-F therebetween. The first non-deformation part NTF1-F may correspond to a first non-folding region NFA1. The second non-deformation part NTF2-F may correspond to a second non-folding region NFA2. The deformation part TF-F may correspond to a folding region FA1. The deformation part TF-F may be a part which is foldable for a folding operation.

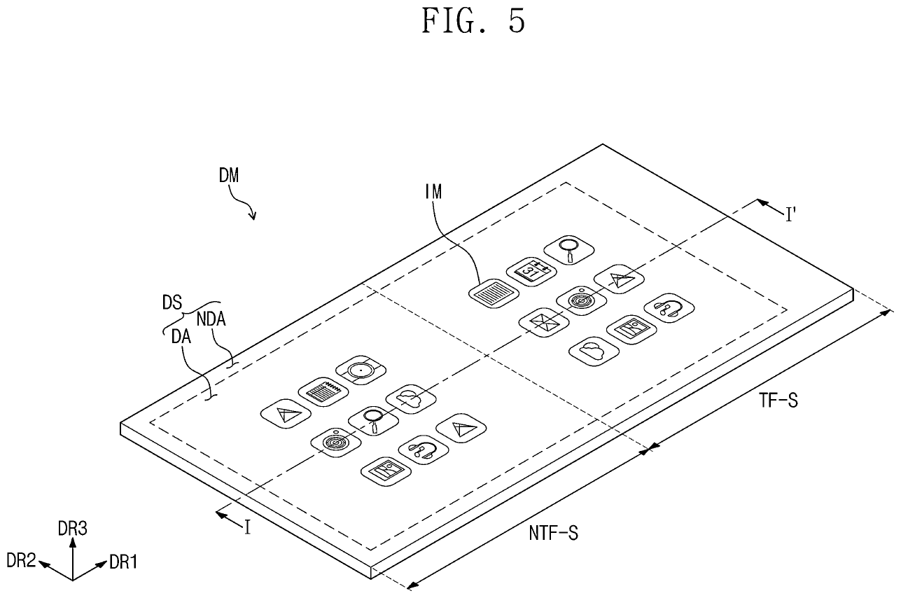

The cover window WP may be a flexible cover window. The cover window WP may protect the display panel DP, etc. The video (or image) IM-b (see FIG. 3A) generated in or output from the display panel DP may pass through the cover window WP, and may be provided to a user. The cover window WP may include a first cover part CV1 (see FIG. 9C) including crystallized glass, and a second cover part CV2 (see FIG. 9C) not including the crystallized glass. The first cover part CV1 (see FIG. 9C) may overlap the non-deformation parts NTF1-F and NTF2-F, and the second cover part CV2 (see FIG. 9C) may overlap the deformation part TF-F. In an embodiment, the cover window WP includes the first cover part CV1 (see FIG. 9C) including the crystallized glass and the second cover part CV2 (see FIG. 9C) not including the crystallized glass, such that the thickness difference between the first and second cover parts CV1 and CV2 (see FIG. 9C) may be reduced, and the impact resistance may be improved. In addition, the display device DD-b including the cover window WP, according to an embodiment, may have high impact resistance. The cover window WP will be described in greater detail later.

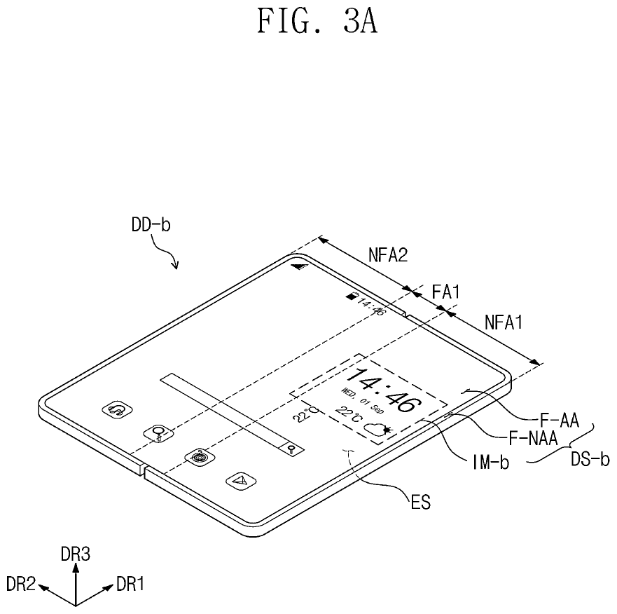

FIG. 5 is a perspective view of a display module DM accommodated in the case CS illustrated in FIG. 1A. Referring to FIG. 5, the display module DM may have a rectangular shape including long sides parallel to a first direction DR1 and short sides parallel to a second direction DR2. However, this is an example, and the shape of the display module DM is not limited thereto.

The display module DM may include a display surface DS. The display surface DS may include a flat surface defined by the first directional axis DR1 and the second directional axis DR2. A video (or image) IM may be displayed through the display surface DS.

The display surface DS may include a display region DA and a non-display region NDA adjacent to the display region DA. The display region DA may display the video IM, and the non-display region NDA may not display the video IM. The non-display region NDA may be adjacent to the display region DA and may surround at least a portion of the display region DA. Although not illustrated in the drawing, a drive circuit, etc. may be disposed on one side of the non-display region NDA.

The display module DM may include a deformation part TF-S and a non-deformation part NTF-S adjacent to the deformation part TF-S. The deformation part TF-F may be a part which is curvedly deformable for a sliding operation. The deformation part TF-S may be a part accommodated in a first case CS1 in a first mode. In the first mode, the non-deformation part NTF-S may correspond to the display surface exposed through a display opening C-OP. In the first mode, the display surface corresponding to the deformation part TF-S may not be exposed through the display opening C-OP. In a second mode, at least a portion of the deformation part TF-S may correspond to the display surface exposed through the display opening C-OP.

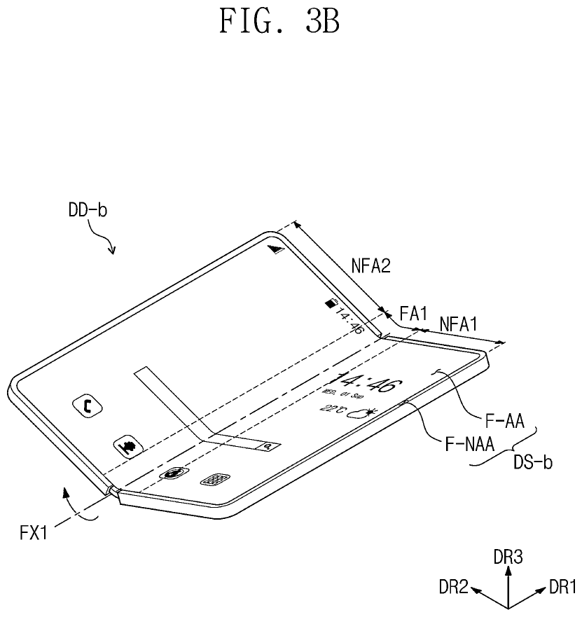

FIG. 6 is a perspective view illustrating a state where the display module illustrated in FIG. 5 is wound. FIG. 6 may be a view illustrating the display module DM in the first mode described above. In the first mode, the deformation part TF-S may be accommodated in the first case CS1 (see FIG. 1A) in a wound state. As the first case CS1 moves along a first direction DR1, at least a portion of the deformation part TF-S may be exposed through the display opening C-OP in the second mode.

FIG. 7 is a cross-sectional view illustrating a portion taken along line I-I′ of FIG. 5. FIG. 7 may be a cross-sectional view of an embodiment of the display module DM corresponding to the display module DM illustrated in FIG. 5. Hereinafter, an embodiment of the display module DM will be described in detail with reference to FIG. 7, and the display module DM may also correspond to the display module DM-a illustrated in FIGS. 2A and 2B or the display module DM-b illustrated in FIG. 4.

The display module DM may include a display panel DP, an input-sensing layer ISL, and a cover window WP. In addition, the display module DM may further include an optical layer RPL disposed between the input-sensing layer ISL and the cover window WP, and a panel protection layer PPL disposed under the display panel DP.

The panel protection layer PPL may protect a lower part of the display panel DP. In an embodiment, for example, the panel protection layer PPL may include polyimide or polyethylene terephthalate.

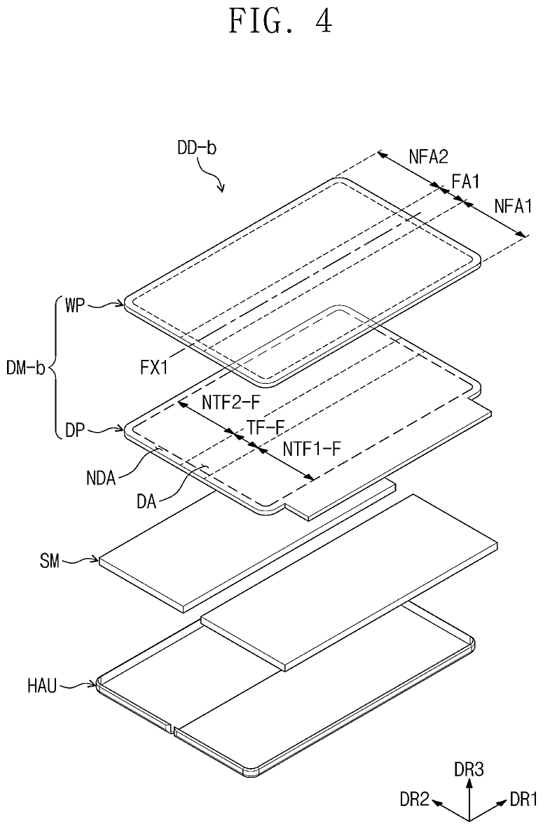

The display panel DP may be a component that generates a video. FIG. 8 is a schematic cross-sectional view illustrating a display panel. Referring to FIG. 8, an embodiment of the display panel DP may include a base substrate BS, a circuit layer DP-CL, a light-emitting element layer DP-ED, and an encapsulation layer TFE which are stacked in sequence. In an embodiment, a functional layer (not shown) may further be disposed between the adjacent two layers among the base substrate BS, the circuit layer DP-CL, the light-emitting element layer DP-ED, and the encapsulation layer TFE.

The base substrate BS may provide a base surface on which the circuit layer DP-CL is disposed. The base substrate BS may be a flexible substrate capable of bending, folding, rolling, etc. The base substrate BS may be a glass substrate, a metal substrate, a polymer substrate, or the like. However, an embodiment of the invention is not limited thereto, and the base substrate BS may include an inorganic layer, an organic layer, or a composite material layer.

The base substrate BS may include or be defined by a single layer or multiple layers. In an embodiment, for example, the base substrate BS may include a first synthetic resin layer, a multi-layer or single-layer inorganic layer, a second synthetic resin layer disposed above the multi-layer or single-layer inorganic layer. The first synthetic resin layer and the second synthetic resin layer may each include a polyimide-based resin. In addition, the first synthetic resin layer and the second synthetic resin layer may each include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In this specification, the term “˜˜-based” resin refers to including the functional group of “˜˜”.

The circuit layer DP-CL may be disposed above the base substrate BS. The circuit layer DP-CL may include an insulation layer, a semiconductor pattern, a conductive pattern, a signal line, or the like. The light-emitting element layer DP-ED may be disposed above the circuit layer DP-CL. The light-emitting element layer DP-ED may include a light-emitting element. For example, the light-emitting element may include an organic light-emitting material, an inorganic light-emitting material, an organic-inorganic light-emitting material, quantum dots, quantum rods, a micro-LED, or a nano-LED.

The encapsulation layer TFE may be disposed above the light-emitting element layer DP-ED. The encapsulation layer TFE may protect the light-emitting element layer DP-ED from moisture, oxygen, and foreign substances such as dust particles. The encapsulation layer TFE may include at least one inorganic layer. In an embodiment, for example, the encapsulation layer TFE may have a structure in which an inorganic layer, an organic layer, and an inorganic layer are stacked in sequence.

Referring back to FIG. 7, the input-sensing layer ISL may be disposed on the display panel DP. The input-sensing layer ISL may be directly disposed on the encapsulation layer TFE (see FIG. 8) of the display panel DP. Alternatively, an adhesion member may also be disposed between the input-sensing layer ISL and the display panel DP.

In this specification, one component directly disposed on the other component means that there is no intervening component disposed between the one component and the other component. That is, one component “directly disposed” on the other component means that the one component is “in contact with” the other component.

The input-sensing layer ISL may detect an external input, and covert the external input to a predetermined input signal to provide the input signal to the display panel DP. In an embodiment, for example, the input-sensing layer ISL may be a touch-sensing layer that detects a touch. The input-sensing layer ISL may recognize a direct touch by a user, an indirect touch by a user, a direct touch by an object, an indirect touch by an object, or the like.

The input-sensing layer ISL may detect at least one of the position where a touch is applied from the outside or the strength (pressure) of the touch. The input-sensing layer ISL may have various structures or may be composed of various materials, and is not limited to any one embodiment of the invention. In an embodiment, for example, the input-sensing layer ISL may detect the external input in a capacitive manner. The display panel DP may receive an input signal from the input-sensing layer ISL, and generate a video corresponding to the input signal.

The optical layer RPL may be disposed on the input-sensing layer ISL. The optical layer RPL may be disposed on the display panel DP, and may control reflected light of external light on the display panel DP. The optical layer RPL may include, for example, a polarizer or a color filter layer.

The cover window WP may include a base window WL and a print layer PIL. In addition, the cover window WP may further include an anti-fingerprint layer AF. The base window WL may include a glass substrate. The base window WL may be optically transparent. In an embodiment, for example, the base window WL may have a light transmittance of at least about 90% for light in a wavelength region of about 380 nanometers (nm) to about 780 nm. The base window WL may include crystallized glass and amorphous glass. The base window WL will be described in greater detail later.

The anti-fingerprint layer AF may be disposed on an upper surface of the base window WL. In an embodiment, for example, the anti-fingerprint layer AF may include a fluorine-based anti-fingerprinting agent. However, this is an example, the anti-fingerprinting agent included in the anti-fingerprint layer AF is not limited thereto.

The print layer PIL may be disposed on a lower surface of the base window WL. The print layer PIL may be disposed on the edge of the base window WL. The print layer PIL may overlap the non-display region NDA (see FIG. 5). In an embodiment, for example, the print layer PIL may include a black pigment or a black dye. However, this is an example, and the material included in the print layer PIL is not limited thereto.

The display module DM may further include first to third adhesive layers 100, 200, and 300. The first adhesive layer 100 may be disposed between the panel protection layer PPL and the display panel DP. The panel protection layer PPL and the display panel DP may be bonded to each other by the first adhesive layer 100. The second adhesive layer 200 may be disposed between the input-sensing layer ISL and the optical layer RPL. The input-sensing layer ISL and the optical layer RPL may be bonded to each other by the second adhesive layer 200. The third adhesive layer 300 may be disposed between the optical layer RPL and the cover window WP. The optical layer RPL and the cover window WP may be bonded to each other by the third adhesive layer 300. The first to third adhesive layers 100, 200, and 300 may each include a general adhesive such as a pressure sensitive adhesive (PSA), an optically clear adhesive (OCA), or an optical clear resin (OCR), and are not limited to any one embodiment of the invention. In an alternative embodiment, at least one of the first to third adhesive layers 100, 200, or 300 may be omitted.

FIG. 9A is a cross-sectional view illustrating the base window, illustrated in FIG. 6, in detail. FIG. 9A may be a cross-sectional view illustrating the base window included in a cover window according to an embodiment. Referring to FIG. 9A, the base window WL may include first and second cover parts CV1 and CV2. The first cover part CV1 may overlap or correspond to a non-deformation part NTF-S. The second cover part CV2 may overlap or correspond to a deformation part TF-S.

The first cover part CV1 may have a first thickness T1 in a range of about 100 micrometers (μm) to about 1000 μm. The first cover part, when having the first thickness greater than about 1000 μm, increases the thickness of the display device. The first cover part, when having the first thickness less than about 100 μm, may be vulnerable to external impact. The first cover part CV1 having the first thickness T1 in a range of about 100 μm to about 1000 μm may have high impact resistance without substantially increasing the thickness of the display device DD. The first cover part CV1 may include crystallized glass. The crystallized glass may be formed by amorphous glass being crystallized by laser irradiation. The crystallized glass may include a crystal GC formed by the laser irradiation. The diameter of the crystal GC may be in a range of about 10 nm to about 100 nm. In an embodiment, for example, the diameter of the crystal GC may be in a range of about 20 nm to about 40 nm. The first cover part CV1 including the crystal GC having a diameter less than about 100 nm may be characterized by a high transmittance for light in the visible light wavelength region, and a low haze value. For example, the first cover part CV1 including the crystal GC having the diameter less than about 100 nm may have a transmittance of at least about 90% in the wavelength region of about 380 nm to about 780 nm. Accordingly, the base window WL including the crystal GC having the diameter less than about 100 nm may have high optical characteristics.

The first cover part, when including the crystal GC having the diameter greater than about 100 nm, may be characterized by a low transmittance for light in the visible light wavelength region, and a high haze value. Accordingly, the base window including the crystal having the diameter greater than about 100 nm may not be effectively used as a component of the display device.

The first cover part CV1 including the crystallized glass may have high impact resistance. Since the first cover part CV1 includes the crystal GC which is formed by particles constituting glass being crystallized, the first cover part CV1 may have improved mechanical strength to have high impact resistance.

The second cover part CV2 may not include the crystallized glass. The second cover part CV2 may include the amorphous glass. The second cover part CV2 including the amorphous glass may easily perform sliding and folding operations.

The second cover part CV2 overlapping the deformation part TF-S may have a second thickness T2 less than the first thickness T1 of the first cover part CV1. The thickness T2 of the second cover part CV2 overlapping the deformation part TF-S may be formed to be relatively thin to facilitate the sliding and folding operations. The second thickness T2 of the second cover part CV2 may be in a range of about 10 μm to about 100 μm. The second cover part, when having the thickness less than about 10 μm, lacks durability, such that the display device including the second cover part, the thickness of which is less than about 10 μm, may have decreased reliability. When the second cover part has the thickness greater than about 100 μm which is relatively large, it may not be easy to perform the folding and sliding operations. In an embodiment, the second cover part CV2 having the second thickness T2 less than or equal to about 100 μm may have characteristics of easy folding and sliding.

The base window WL may include a third cover part CV3 disposed between the first cover part CV1 and the second cover part CV2. The first to third cover parts CV1, CV2, and CV3 may have an integral shape or be integrally formed with each other as a single unitary and indivisible part. The third cover part CV3 may not include the crystallized glass, and may include the amorphous glass. The third cover part CV3 may include a slope (or sloped portion) FS. The third cover part CV3 may have the first thickness T1 on one end adjacent to the first cover part CV1, and have the second thickness T2 on the other end adjacent to the second cover part CV2. In an embodiment, for example, the angle between the slope FS of the third cover part CV3 and a lower surface 1_DF of the first cover part CV1 may be greater than about 90° and less than about 180°.

The base window WL may further include a coating layer RS overlapping the second cover part CV2. The coating layer RS may not overlap the first cover part CV1. The coating layer RS may be directly disposed on a lower surface 2_DF of the second cover part CV2. One region of the coating layer RS may overlap the second cover part CV2, and the other region of the coating layer RS may overlap the third cover part CV3. A thickness T3 of the coating layer RS may be substantially the same as the difference between the first thickness T1 of the first cover part CV1 and the thickness T2 of the second cover part CV2. The total thickness of the thickness T3 of the coating layer RS and the thickness T2 of the second cover part CV2 may be substantially the same as the first thickness T1 of the first cover part CV1. The coating layer RS may be formed in a way such that the base window WL has a substantially flat lower surface. In this specification, the meaning of being substantially the same includes not only the case where numerical values are physically the same, but also the case where the values differ within a generally possible error range in a process.

The refractive index of the coating layer RS may be substantially the same as the refractive index of the second cover part CV2. The coating layer RS including or formed of a material having a same refractive index as that of the second cover part CV2 may maintain optical characteristics of the base window WL. The coating layer RS may be formed by providing an optically transparent polymer resin. The polymer resin may have a same refractive index as that of the second cover part CV2. In an embodiment, for example, the coating layer RS may include an acrylate-based resin.

In an embodiment of the display device capable of sliding or folding operation, the base window included in the cover window includes one portion (that is, second cover part) having a relatively thin thickness. The one portion having the relatively thin thickness overlaps a portion slidable or foldable (that is, deformation part). In case of reducing the thickness of the second cover part for easy sliding or folding, the thickness difference between the first cover part and the second cover part becomes increasing. When the thickness difference between the first cover part and the second cover part increases, the thickness difference may cause defects to occur. As the thickness difference becomes increasing, it may not be easy to manufacture the first cover part and/or the second cover part in uniform thickness, and it may be difficult to apply chemical strengthening treatment uniformly to the first cover part and the second cover part. The chemical strengthening treatment includes a process of immersing glass in molten salt to increase the strength of the glass. In addition, in case of reducing the thickness of the first cover part for reducing the thickness difference between the first cover part and the second cover part, the impact resistance may become degraded.

In an embodiment, the base window WL included in the cover window WP includes the first cover part CV1 including the crystallized glass and the second cover part CV2 including the amorphous glass, such that the thickness difference between the first cover part CV1 and the second cover part CV2 may be reduced, and it may be possible for the cover window WP to have high impact resistance. In such an embodiment, since the first cover part CV1 includes the crystallized glass while reducing the difference between the first thickness T1 of the first cover part CV1 and the thickness T2 of the second cover part CV2, the mechanical strength may be improved. In such an embodiment, the base window WL may have characteristics of easy sliding. Accordingly, the display device DD including the cover window WP may have high impact resistance and have characteristics of easy sliding.

FIG. 9B is a cross-sectional view illustrating another embodiment of the invention, and illustrating a cover window included in the display device illustrated in FIGS. 2A and 2B. Hereinafter, for the description with reference to FIG. 9B, any repetitive detailed description of the same or like elements as those described above with reference to FIGS. 1A to 9A will be omitted, and the differences will be mainly described.

In particular, FIG. 9B may illustrate an embodiment of a base window WL-a included in the display device DD-a illustrated in FIGS. 2A and 2B. In such an embodiment, the base window WL-a illustrated in FIG. 9B may be substantially the same as the based window WL illustrated in FIG. 9A except that a second cover part CV2 includes first and second sub-cover parts CV2-a and CV2-aa. In addition, in the base window WL-a illustrated in FIG. 9B, a third cover part CV3 may include third and fourth sub-cover parts CV3-a and CV3-aa.

Referring to FIGS. 2A, 2B, and 9B, an embodiment of the display module DM-a illustrated in FIGS. 2A and 2B may include two deformation parts TF-S and TF-Sa and one non-deformation part NTF-S. The display module DM-a may include a first deformation part TF-S, a second deformation part TF-Sa, and a non-deformation part NTF-S disposed between the first deformation part TF-S and the second deformation part TF-Sa. The first deformation part TF-S and the second deformation part TF-Sa may be portions which is curvedly deformable (e.g., bendable or rollable) for a sliding operation. As the first case CS1 (see FIG. 2B) moves along a first direction DR1, the first deformation part TF-S may be exposed through the display opening C-OP (see FIG. 2B). As the third case CS3 (see FIG. 2B) moves along a fourth direction DR4, the second deformation part TF-Sa may be exposed through the display opening C-OP (see FIG. 2B). The first deformation part TF-S may be a part accommodated in the first case CS1 (see FIG. 2A). The second deformation part TF-Sa may be a part accommodated in the third case CS3 (see FIG. 2A).

The second cover part CV2 may overlap the first deformation part TF-S and the second deformation part TF-Sa. The second cover part CV2 may include the first sub-cover part CV2-a and the second sub-cover part CV2-aa. The first sub-cover part CV2-a may overlap the first deformation part TF-S, and the second sub-cover part CV2-aa may overlap the second deformation part TF-Sa.

The third cover part CV3 may include the third sub-cover part CV3-a and the fourth sub-cover part CV3-aa. The third sub-cover part CV3-a may be disposed between the first sub-cover part CV2-a and the first cover part CV1. The fourth sub-cover part CV3-aa may be disposed between the second sub-cover part CV2-aa and the first cover part CV1. The third sub-cover part CV3-a and the fourth sub-cover part CV3-aa may be spaced apart from each other with the first cover part CV1 therebetween. The first cover part CV1 and the first to fourth sub-cover parts CV2-a, CV2-aa, CV3-a, and CV3-aa may have an integral shape or be integrally formed with each other as a single unitary and indivisible part. The first to fourth sub-cover parts CV2-a, CV2-aa, CV3-a, and CV3-aa may include amorphous glass. The first cover part CV1 may include crystallized glass. Accordingly, the display device DD-a including the base window WL-a may have high impact resistance and have characteristics of easy sliding.

Coating layers RS-a and RS-aa may be disposed on lower surfaces 2a_DF and 2aa_DF of the first and second sub-cover parts CV2-a and CV2-aa, respectively. The first coating layer RS-a may be directly disposed on the lower surface 2a_DF of the first sub-cover part CV2-a. The refractive index of the first coating layer RS-a may be substantially the same as the refractive index of the first sub-cover part CV2-a. The second coating layer RS-aa may be directly disposed on the lower surface 2aa_DF of the second sub-cover part CV2-aa. The refractive index of the second coating layer RS-aa may be substantially the same as the refractive index of the second sub-cover part CV2-aa.

One region of the first coating layer RS-a may overlap the first sub-cover part CV2-a, and the other region of the first coating layer RS-a may overlap the third sub-cover part CV3-a. The one region of the first coating layer RS-a may be a region extending from the other region of the first coating layer RS-a in a first direction DR1. The other region of the first coating layer RS-a may be in contact with a slope FS-a of the third sub-cover part CV3-a.

The other region of the second coating layer RS-aa may overlap the second sub-cover part CV2-aa, and one region of the second coating layer RS-aa may overlap the fourth sub-cover part CV3-aa. The one region of the second coating layer RS-aa may be a region extending from the other region of the second coating layer RS-aa in the first direction DR1. The one region of the second coating layer RS-aa may be in contact with a slope FS-aa of the fourth sub-cover part CV3-aa.

FIG. 9C is a cross-sectional view illustrating another embodiment of the invention, and illustrating a cover window included in the display device described with reference to FIGS. 3A to 4. Hereinafter, for the description with reference to FIG. 9C, any repetitive detailed description of the same or like elements as those described with reference to FIGS. 1A to 9B will be omitted, and the differences will be mainly described.

In particular, FIG. 9C may illustrate an embodiment of a base window WL-b included in the display device DD-b illustrated in FIGS. 3A to 4. The base window WL-b illustrated in FIG. 9C is substantially the same as the base window WL illustrated in FIG. 9A except that a first cover part CV1 includes fifth and sixth sub-cover parts CV1-b and CV1-bb. In addition, in the base window WL-b illustrated in FIG. 9C, a third cover part CV3 may include seventh and eighth sub-cover parts CV3-b and CV3-bb.

As described above, an embodiment of the display module DM-b illustrated in FIG. 4 may include a first non-deformation part NTF1-F, a second non-deformation part NTF2-F, and a deformation part TF-F disposed between the first non-deformation part NTF1-F and the second non-deformation part NTF2-F. The deformation part TF-F may be a part which is curvedly deformable (e.g., foldable) for a folding operation.

The first cover part CV1 may overlap the first non-deformation part NTF1-F and the second non-deformation part NTF2-F. The first cover part CV1 may include the fifth sub-cover part CV1-b and the sixth sub-cover part CV1-bb. The fifth sub-cover part CV1-b may overlap the first non-deformation part NTF1-F, and the sixth sub-cover part CV1-bb may overlap the second non-deformation part NTF2-F.

The third cover part CV3 may include the seventh sub-cover part CV3-b and the eighth sub-cover part CV3-bb. The seventh sub-cover part CV3-b may be disposed between the second cover part CV2 and the fifth sub-cover part CV1-b. The eighth sub-cover part CV3-bb may be disposed between the sixth sub-cover part CV1-bb and the second cover part CV2. The second cover part CV2 may be disposed between the seventh sub-cover part CV3-b and the eighth sub-cover part CV3-bb. The second cover part CV2 and the fifth to eighth sub-cover parts CV1-b, CV1-bb, CV3-b, and CV3-bb may have an integral shape or be integrally formed with each other as a single unitary and indivisible part. The fifth and sixth sub-cover parts CV1-b and CV1-bb may include crystallized glass. The second cover part CV2, the seventh sub-cover part CV3-b, and the eighth sub-cover part CV3-bb may include amorphous glass. Accordingly, the display device DD-b including the base window WL-b may have high impact resistance and have characteristics of easy folding.

A coating layer RS-b may be directly disposed on a lower surface 2_DF of the second cover part CV2. The refractive index of the coating layer RS-b may be substantially the same as the refractive index of the second cover part CV2.

An edge region on one side of the coating layer RS-b may be in contact with a slope FS-b of the seventh sub-cover part CV3-b. An edge region on the other side of the coating layer RS-b may be in contact with a slope FS-bb of the eighth sub-cover part CV3-bb. The edge region on one side of the coating layer RS-b and the edge region on the other side of the coating layer RS-b may be spaced apart from each other in a second direction DR2, and may not overlap the second cover part CV2.

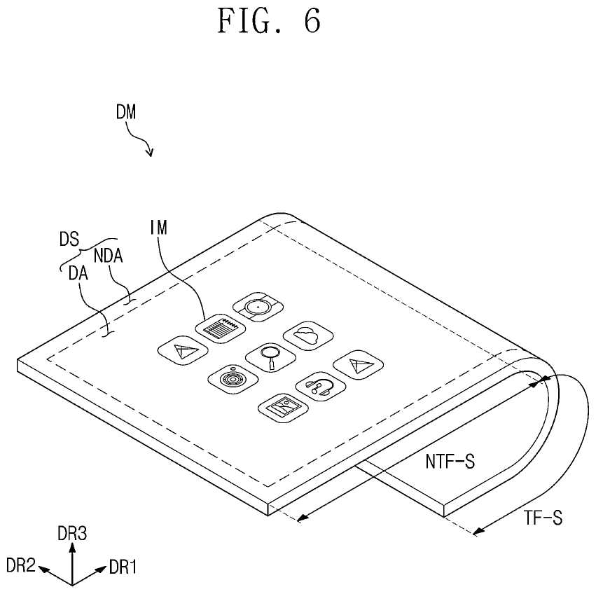

FIG. 10 is a graph showing ball drop test results of a cover window in Comparative Example 1, and a cover window in Example 1. FIG. 10 shows the ball drop height at which damage occurs to the cover window of each of Comparative Example 1 and Example 1 when dropping the ball to the cover window disposed on a rough surface of sandpaper. The cover window of Example 1 is the cover window, according to an embodiment, including crystallized glass, and the cover window of Comparative Example 1 does not include the crystallized glass. The cover window of Comparative Example 1 and the cover window of Example 1 differ from each other only in whether or not including the crystallized glass. A ball used in the ball drop test has a size of about 6 pi (φ) and a weight of about 1 gram (g).

Referring to FIG. 10, compared to the cover window of Comparative Example 1, it may be seen that the cover window of Example 1 has a greater height at which the damage occurs to the cover window. Since the cover window of Example 1 includes the crystallized glass, the mechanical strength is improved, and thus the height at which the damage occurs to cover window is relatively high. Accordingly, in an embodiment, the cover window including the first cover part including the crystallized glass may have high impact resistance.

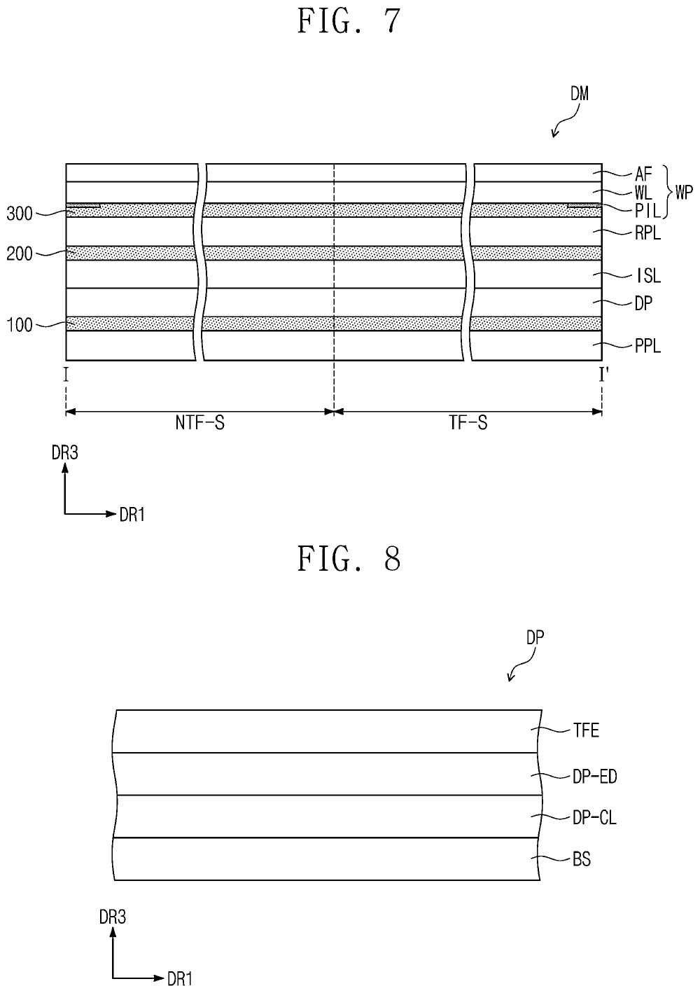

FIG. 11 is a graph showing the light transmittance evaluated according to a wavelength in a cover window of Example 2. The light transmittance by wavelength is evaluated using a spectrophotometer CM-3600D (a product of Konica Minolta). The cover window of Example 2 is the cover window, according to an embodiment, including crystallized glass. The thickness of the cover window of Example 2 is about 600 μm, and the diameter of a crystal of the crystallized glass included in the cover window of Example 2 is in a range of about 20 nm to about 40 nm. The cover window of Example 2 satisfies the diameter range of the crystal according to an embodiment. In an embodiment, the crystallized glass included in the first cover part may be composed of the crystal having the diameter of about 100 nm or less.

Referring to FIG. 11, it may be seen that the cover window of Example 2 has a light transmittance of at least about 90% in the wavelength region of about 380 nm to about 780 nm. Accordingly, in an embodiment, it may be possible that the cover window including the crystallized glass, formed of the crystal having the diameter of about 100 nm or less, may have high optical characteristics.

Table 1 below shows a light transmittance, a haze value, and a yellow index (YI) measured for the cover window of each of Comparative Example 2 and Example 2. Table 1 shows the results of evaluation under the condition of standard light source D65 using the spectrophotometer CM-3600D (a product of Konica Minolta). The light transmittance value is measured in the wavelength of about 550 nm.

The cover window of Comparative Example 2 includes the crystallized glass, and the crystals each of which has a diameter of about 200 nm to about 350 nm. As described with reference to FIG. 11, the cover window of Example 2 is the cover window, according to an embodiment, including the crystals, each having diameter of about 20 nm to about 40 nm. The cover window of Comparative Example 2 and the cover window of Example 2 differ from each other only in size of the crystal. When the haze value is about 0.5% or less, it is determined to be high, and when the yellow index is about 1.0 or less, it is determined to be high.

TABLE 1

| | Transmittance | Haze value | Yellow index |
|---|---|---|---|
| | (Tr, %, 550 nm) | (Haze, %) | (YI) |
| Comparative | 90.53% | 0.29% | 0.71 |
| Example 2 | | | |
| Example 2 | 84.20% | 4.40% | 1.58 |

Referring to Table 1, it may be seen that the cover window of Example 2 has a light transmittance of about 90% or greater, a haze value of about 0.5% or less, and a yellow index of about 1.0 or less. The cover window of Example 2 includes the crystallized glass composed of crystals, each having a diameter in a range of about 20 nm to about 40 nm, and it may be seen that the cover window of Example 2 has high optical characteristics.

On the other hand, it may be seen that the cover window of Comparative Example 2 has a relatively low light transmittance, a haze value greater than about 0.5%, and a yellow index greater than about 1.0. The cover window of Comparative Example 2 includes the crystallized glass composed of crystals, each having a diameter in a range of about 200 nm to about 350 nm, relatively large in diameter, and thus it may be seen that the optical characteristics are degraded.

The cover window according to an embodiment may include a first cover part overlapping a non-deformation part and including crystallized glass, and a second cover part overlapping a deformation part which is curvedly deformable for a folding or sliding operation, and not including the crystallized glass. Accordingly, the cover window may have improved impact resistance while reducing the thickness difference between the first cover part and the second cover part. The display device including the cover window according to an embodiment may have high impact resistance, and have characteristics of easy folding and sliding.

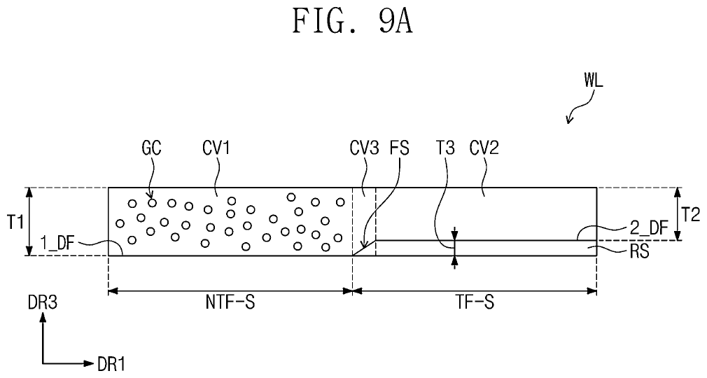

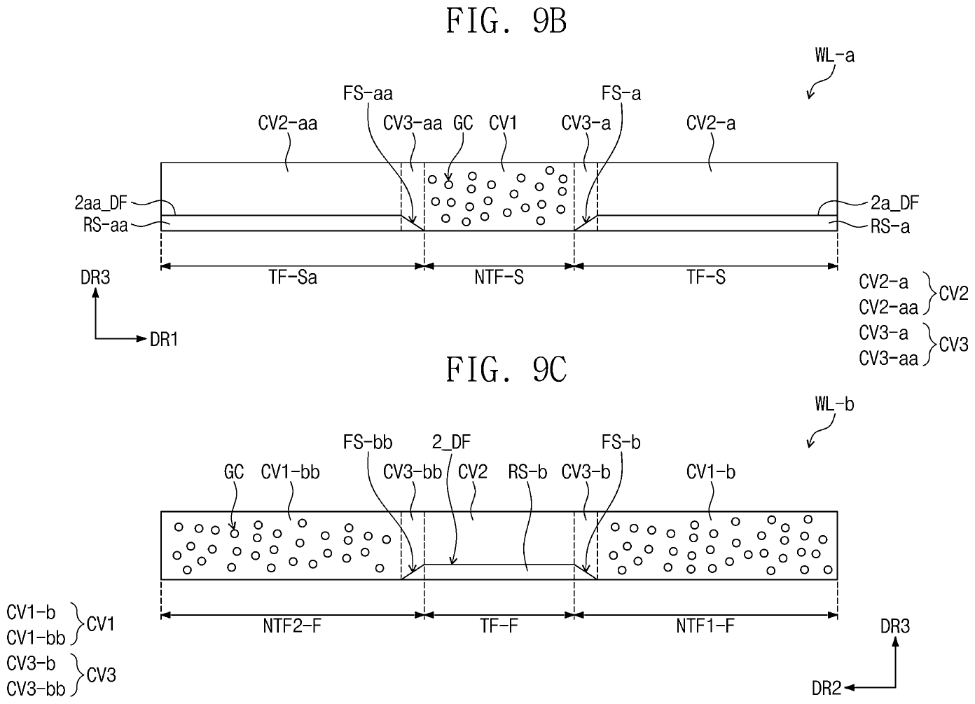

The display device according to an embodiment may be formed by a manufacturing method for a display device according to an embodiment. FIGS. 12A and 12B are flowcharts illustrating a manufacturing method for a display device according to an embodiment. FIGS. 13 to 17 are diagrams schematically illustrating manufacturing operations of a display device according to an embodiment. Hereinafter, for the description with reference to FIGS. 12A to 17, any repetitive detailed description of the same or like elements as those described above with reference to FIGS. 1A to 11 will be omitted, and the differences will be mainly described.

Referring to FIGS. 12A and 12B, the manufacturing method for the display device according to an embodiment may include preparing a display panel S100 and forming a cover window S200. As described with reference to FIGS. 4, 7, and 9A to 9C, the display panel DP may include the deformation part TF-F, TF-S, or TF-Sa, and the non-deformation part NTF1-F, NTF2-F, or NTF-S adjacent to the deformation part TF-F, TF-S, or TF-Sa. The deformation part TF-F, TF-S, or TF-Sa may be a part which is curvedly deformable for a sliding or folding operation. The cover window WL, WL-a, or WL-b may include the first cover part CV1 overlapping the non-deformation part NTF1-F, NTF2-F, or NTF-S and including crystallized glass, and the second cover part CV2 overlapping the deformation part STF-F, TF-S, or TF-Sa and not including the crystallized glass.

The forming of the cover window S200 may include preparing a preliminary cover window S210, forming the first cover part S220, and forming the second cover part S230. In an embodiment, as shown in FIG. 12B, the forming of the second cover part S230 may be performed after the forming of the first cover part S220, but an embodiment of the invention is not limited thereto. In an embodiment, the forming of the first cover part may be performed after the forming of the second cover part. The order of performing the forming of the first cover part and the forming of the second cover part is not limited to any one embodiment of the invention.

Referring to FIG. 13, the preliminary cover window P-WP may include a preliminary first cover part P-CV1 and a preliminary second cover part P-CV2 adjacent to the preliminary first cover part P-CV1. In addition, the preliminary cover window P-WP may include a preliminary third cover part P-CV3 defined between the preliminary first cover part P-CV1 and the preliminary second cover part P-CV2. The preliminary first cover part P-CV1, the preliminary second cover part P-CV2, and the preliminary third cover part P-CV3 may have an integral shape or integrally formed with each other as a single unitary an indivisible part. The preliminary first cover part P-CV1, the preliminary second cover part P-CV2, and the preliminary third cover part P-CV3 may be portions of the preliminary cover window P-WP defined to correspond to first to third cover parts CV1, CV2, and CV3 to be formed, respectively. The preliminary first cover part P-CV1, the preliminary second cover part P-CV2, and the preliminary third cover part P-CV3 may include amorphous glass.

The preliminary cover window P-WP may be a glass substrate including amorphous glass. The glass substrate may include at least one selected from SiO₂, Al₂O₃, B₂O₃, Na₂O and Li₂O, for example. However, this is an example, and the material constituting the glass substrate is not limited thereto.

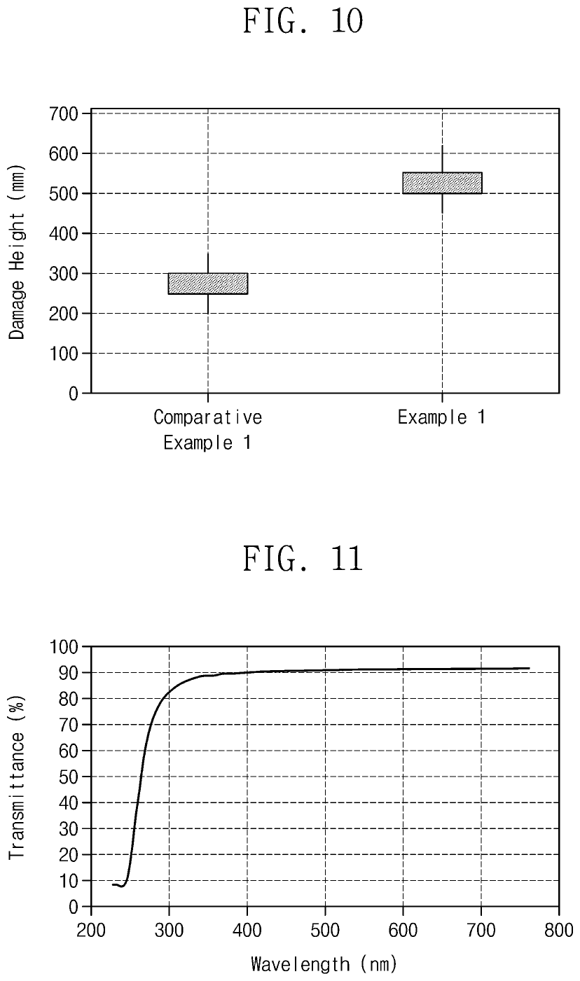

In an embodiment, the first cover part CV1 illustrated in FIG. 14 may be formed by radiating laser LA to the preliminary first cover part P-CV1 as illustrated in FIG. 13. The laser LA may be provided from a laser device LS disposed on one surface of the preliminary first cover part P-CV1. In an embodiment, for example, through an excimer laser annealing (ELA) process, the first cover part CV1 may be formed from the preliminary first cover part P-CV1. The crystallized glass included in the first cover part CV1 may be formed by radiating the laser LA to the amorphous glass included in the preliminary first cover part P-CV1. The first cover part CV1 may include the crystallized glass including or composed of a crystal GC. The diameter of the crystal GC may be in a range of about 10 nm to about 100 nm.

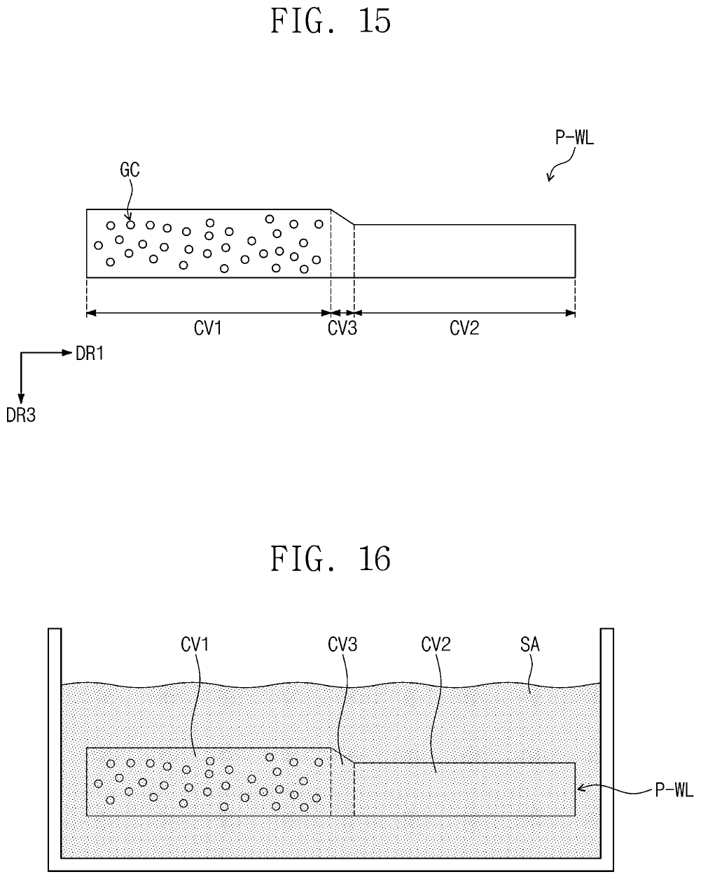

The laser LA may not be radiated to the preliminary second cover part P-CV2 and the preliminary third cover part P-CV3. Accordingly, the second cover part CV2 (see FIG. 17) and the third cover part CV3 (see FIG. 17), respectively formed from the preliminary second cover part P-CV2 and the preliminary third cover part P-CV3, may not include the crystallized glass.

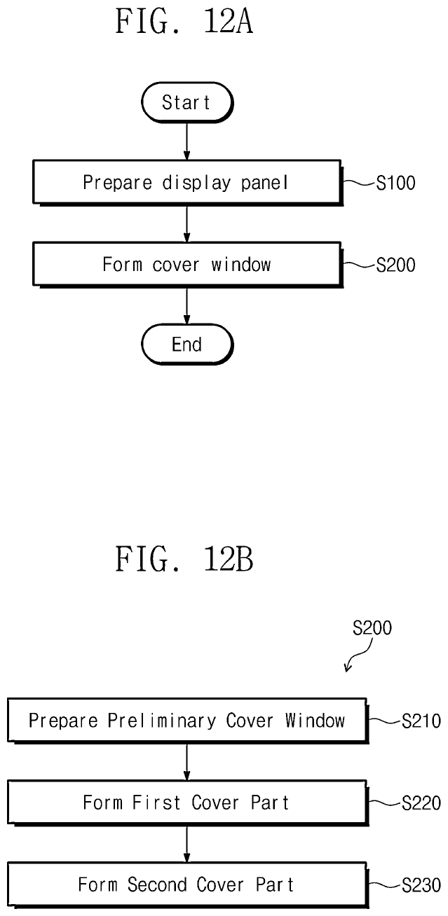

Referring to FIGS. 14 and 15, the preliminary second cover part P-CV2 may be etched to form the second cover part CV2. In an embodiment, for example, the preliminary second cover part P-CV2 may be wet-etched by an etching solution ET. The etching solution ET is not limited to any one embodiment of the invention, and any etching solution known to be used for etching glass in the art may be provided without limitation.

The etching solution ET may not be provided to the first cover part CV1, and the first cover part CV1 may not be etched. Accordingly, the second thickness T2 (see FIG. 9A) of the second cover part CV2 may be formed to be less than the first thickness T1 (see FIG. 9A) of the first cover part CV1.

In addition, a portion of the preliminary third cover part P-CV3 may be etched by the etching solution ET to form the third cover part CV3. Since only a portion of the preliminary third cover part P-CV3 is etched, the third cover part CV3 may have the first thickness T1 (see FIG. 9A) on one end adjacent to the first cover part CV1, and have the second thickness T2 (see FIG. 9A) on the other end adjacent to the second cover part CV2.

In the manufacturing method for the display device according to an embodiment, it is described that the first cover part CV1 is formed by the laser LA, and then the second cover part CV2 is formed by the etching solution ET, but an embodiment of the invention is not limited thereto. In an embodiment, the second cover part CV2 may be formed by the etching solution ET, and then the first cover part CV1 may be formed by the laser LA. The preliminary base window P-WL including the first to third cover parts CV1, CV2, and CV3 may be formed by the laser LA and the etching solution ET.

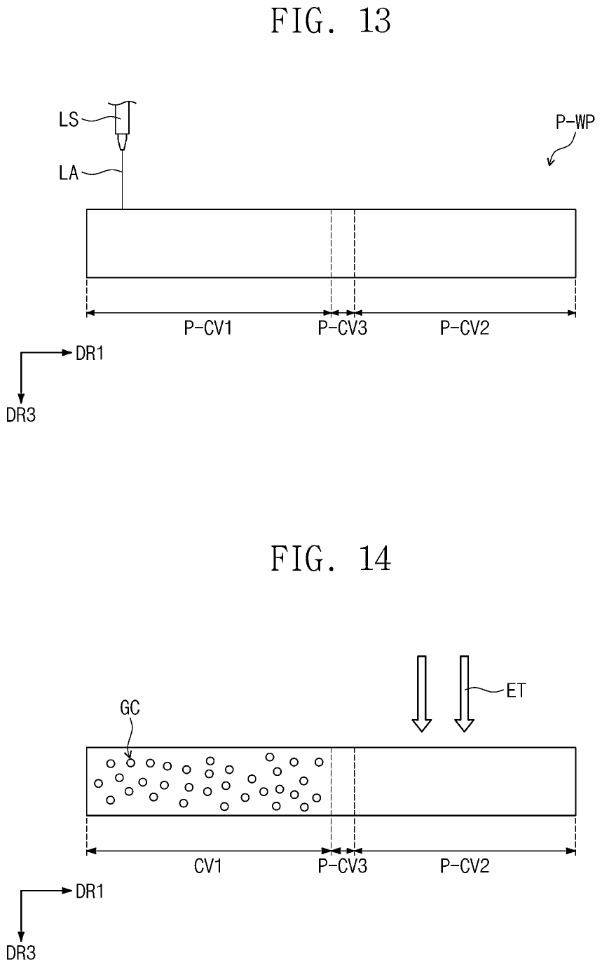

The manufacturing method for the display device according to an embodiment may further include, after the forming of the first cover part CV1 and the forming of the second cover part CV2, immersing the first cover part CV1 and the second cover part CV2 in molten salt SA. Referring to FIG. 16, the preliminary base window P-WL including the first to third cover parts CV1, CV2, and CV3 may be immersed in the molten salt SA. Accordingly, a chemical reinforcement treatment may be performed by ion exchange between the preliminary base window P-WL and the molten salt SA. In an embodiment, for example, Li⁺ ions of the preliminary base window P-WM may be exchanged for Na⁺ ions or K⁺ ions of the molten salt SA. However, this is an example, and the ions included in the preliminary base window P-WL and the ions included in the molten salt SA are not limited to any one embodiment of the invention.

The manufacturing method for the display device according to an embodiment may further include forming a coating layer RS on one surface 2_DF of the second cover part CV2. On the basis of a thickness direction DR3, the one surface 2_DF of the second cover part CV2 may be a lower surface of the second cover part CV2.

Referring to FIG. 17, the coating layer RS may be directly formed on the one surface 2_DF of the second cover part CV2. The coating layer RS may be formed by coating an optically transparent polymer resin. The coating layer RS may include or be formed of a material having substantially a same refractive index as that of the second cover part CV2. In an embodiment, for example, the coating layer RS may be formed by coating an acrylate-based resin. The acrylate-based resin may be provided to have substantially the same refractive index as that of the second cover part CV2. The coating layer RS may not overlap the first cover part CV1 including crystallized glass. The coating layer RS may be in contact with the second cover part CV2 and the third cover part CV3.

The manufacturing method for the display device according to an embodiment may further include forming a print layer PIL and forming an anti-fingerprint layer AF. The print layer PIL may be formed on one surface (for example, a lower surface) of the first cover part CV1, and on one surface (for example, a lower surface) of the second cover part CV2. In an embodiment, for example, the print layer PIL may be directly formed on one surface (for example, lower surface) of the first cover part CV1, and on one surface of the coating layer RS on the second cover part CV2. The anti-fingerprint layer AF may be formed on another surface or the opposing surface (for example, an upper surface) of the first cover part CV1, and on another surface or the opposing surface (for example, an upper surface) of the second cover part CV2.

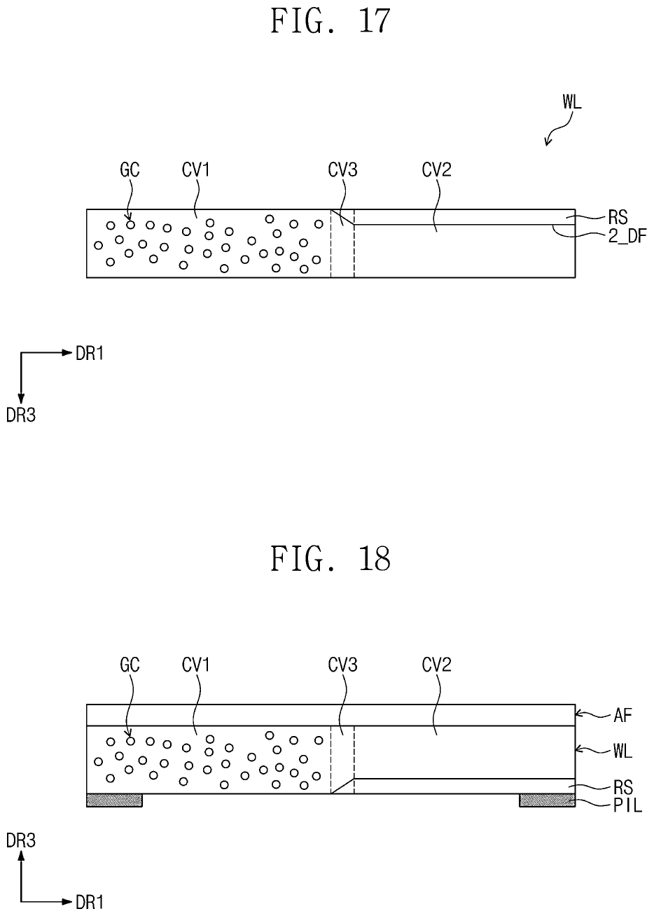

Referring to FIG. 18, the print layer PIL may be formed on one surface (for example, a lower surface) of a base window WL. In an embodiment, for example, the print layer PIL may include or be formed of a black pigment or a black dye.

The anti-fingerprint layer AF may be formed on the other surface (for example, an upper surface) of the base window WL. In an embodiment, for example, a fluorine-based anti-fingerprinting agent may be provided to form the anti-fingerprint layer AF. The cover window WP including the print layer PIL, the anti-fingerprint layer AF, and the base window WL may be provided onto the display panel DP (see FIG. 7).

The manufacturing method for the display device according to an embodiment may include radiating laser. The first cover part including the crystallized glass may be formed by radiating the laser to the preliminary first cover part of the preliminary cover window. The preliminary second cover part may not be irradiated by the laser, and may be etched to form the second cover part. The second cover part may be a part which is curvedly deformable for a folding or sliding operation. The cover window including the first cover part including the crystallized glass and the second cover part not including the crystallized glass may have high impact resistance. Accordingly, the display device including the cover window according to an embodiment, which is formed by the manufacturing method for the display device according to an embodiment, may have high impact resistance. In addition, the display device including the cover window according to an embodiment may have characteristics of easy folding and sliding.

Since a display device according to an embodiment includes a cover window partially including crystallized glass, the display device may be easily slidable or foldable, and may have high impact resistance.

A manufacturing method for a display device according to an embodiment may include radiating laser to form a cover window which partially includes the crystallized glass, thereby forming the display device easily slidable or foldable and having high impact resistance.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
a display panel including a deformation part, which is curvedly deformable, and a non-deformation part adjacent to the deformation part; and
a cover window disposed on the display panel,
wherein the cover window comprises:
a first cover part overlapping the non-deformation part and comprising crystallized glass; and
a second cover part overlapping the deformation part and not comprising the crystallized glass.

2. The display device of claim 1, wherein the crystallized glass comprises a crystal having a diameter in a range of about 10 nm to about 100 nm.

3. The display device of claim 1, wherein the second cover part comprises amorphous glass.

4. The display device of claim 1, wherein the cover window further comprises a coating layer overlapping the second cover part.

5. The display device of claim 4, wherein the coating layer does not overlap the first cover part.

6. The display device of claim 4, wherein a refractive index of the coating layer is substantially the same as a refractive index of the second cover part.

7. The display device of claim 4, wherein the coating layer comprises an optically transparent polymer resin.

8. The display device of claim 1, wherein a first thickness of the first cover part is greater than a second thickness of the second cover part.

9. The display device of claim 1, wherein a thickness of the second cover part is in a range of about 10 μm to about 100 μm.

10. The display device of claim 1, wherein the cover window further comprises a third cover part disposed between the first cover part and the second cover part and including a slope.

11. The display device of claim 10, wherein the third cover part does not comprise the crystallized glass, and comprises amorphous glass.

12. A manufacturing method for a display device, the manufacturing method comprising:
preparing a display panel which includes a deformation part, which is curvedly deformable, and a non-deformation part adjacent to the deformation part; and
forming a cover window which includes a first cover part overlapping the non-deformation part and including crystallized glass and a second cover part overlapping the deformation part and not including the crystallized glass,
wherein the forming the cover window comprises:
preparing a preliminary cover window which includes a preliminary first cover part and a preliminary second cover part adjacent to the preliminary first cover part;
etching the preliminary second cover part to form the second cover part; and
radiating laser to the preliminary first cover part to form the first cover part before or after the forming the second cover part.

13. The manufacturing method of claim 12, wherein the preliminary first cover part comprises amorphous glass, and
the forming the first cover part comprises radiating the laser to the amorphous glass to form the crystallized glass.

14. The manufacturing method of claim 12, wherein the laser is not radiated to the preliminary second cover part.

15. The manufacturing method of claim 12, wherein a thickness of the preliminary second cover part is reduced by the etching.

16. The manufacturing method of claim 12, wherein the etching the preliminary second cover part comprises providing an etching solution to the preliminary second cover part.

17. The manufacturing method of claim 12, wherein the cover window further comprises a third cover part disposed between the first cover part and the second cover part and including a slope, and
the third cover part is formed in a same process as the etching the preliminary second cover part.

18. The manufacturing method of claim 12, wherein the forming the cover window further comprises, after the forming the first cover part and the forming the second cover part, immersing the first cover part and the second cover part in molten salt.

19. The manufacturing method of claim 12, wherein the forming the cover window further comprises, after the forming the first cover part and the forming the second cover part, forming a coating layer on one surface of the second cover part by providing an optically transparent polymer resin thereon.

20. The manufacturing method of claim 12, wherein the forming the cover window further comprises, after the forming the first cover part and the forming the second cover part:
forming a print layer on one surface of the first cover part and one surface of the second cover part; and
forming an anti-fingerprint layer on another surface of the first cover part and another surface of the second cover part.
